(19) United States
(12) Patent Application Publication
(10) Pub. No.: US 2024/0347765 A1
(43) Pub. Date: Oct. 17, 2024

(54) METHOD OF PRODUCING GARNET-TYPE SOLID ELECTROLYTES

(71) Applicant: THE ROYAL INSTITUTION FOR THE ADVANCEMENT OF LEARNING/MCGILL UNIVERSITY, Montréal (CA)

(72) Inventors: George P. DEMOPOULOS, Montreal (CA); Hsien-Chieh CHIU, Taoyuan City (TW)

(21) Appl. No.: 18/685,334

(22) PCT Filed: Aug. 24, 2022
(86) PCT No.: PCT/CA2022/051278

§ 371 Date: Feb. 21, 2024

Related U.S. Application Data
(60) Provisional application No. 63/236,533, filed on Aug. 24, 2021.

(51) Int. Cl. H01M 10/0562

(52) U.S. Cl. CPC H01M 10/0562; H01M 2300/0077

(57) ABSTRACT

There is provided a method of producing LLZO having a cubic crystal phase. The method comprises providing an aqueous phase comprising zirconium (Zr) and lanthanum (La). The aqueous phase has a pH of between 7 and 14. An intermediate is formed, the intermediate comprising crystalline La(OH)₃ and amorphous Zr hydroxide from the Zr and the La in the aqueous phase. The intermediate is washed and recovered to obtain a washed intermediate. The washed intermediate is heat treated with a Li precursor at a temperature of from 400 to 850° C. to obtain the LLZO.

### TECHNICAL FIELD

This disclosure relates to the field of Li-ion conductors, specifically garnet-type electrolytes and methods of making same.

### BACKGROUND OF THE ART

Solid-state lithium ion secondary batteries with inorganic solid electrolytes are of interest in the field of energy storage because of their high safety, reliability and energy density. Oxide materials belonging to the garnet family with a composition of LiₓLa₃M₂O₁₂ (where x=5 or 7, M=Ta, Nb, and/or Zr) have been extensively investigated recently as promising Li-ion conductors. They are of a particular interest for their chemical stability and handling. Recently, garnet-type Li₇La₃Zr₂O₁₂ (LLZO) has been studied extensively because LLZO has high lithium ion conductivity (up to 10⁻³ S·cm⁻¹ at room temperature) in cubic phase and chemical stability against lithium metal. Although the bulk conductivity is close to 10⁻³ S·cm⁻¹, available processes of producing LLZO require a very high temperature for obtaining the Li-ion conducting cubic crystal phase as opposed to the less conductive tetragonal phase. Indeed, to obtain the cubic LLZO, known methods necessitate a heat-treatment at around 1100-1200° C., for example a 1200° C. temperature is required in the conventional solid-state reaction method. Such a heat-treatment at high temperatures causes a lithium loss, and to suppress the lithium loss, samples must be covered with mother powders.

U.S. Pat. No. 9,461,331 B2 describes using an aqueous-based aging treatment to prepare a crystalline intermediate in the temperature range of from 140 to 250° C. followed by high temperature calcination. The high temperature calcination is divided in two steps, in the first step tetragonal LLZO is obtained at a calcination temperature of from 700 to 900° C. for 6 to 12 h. And, at the second step, to obtain the cubic phase LLZO, a second calcination treatment at a temperature of 1000 to 1100° C. for 6 to 12 h is necessarily performed on the resulting tetragonal LLZO from the first step.

The existing methods are thus deficient in at least (1) the high processing temperature needed; (2) the difficulty in preparing high-purity or nanosized garnet-type cubic phase solid electrolyte; and (3) the requirement for non-sustainable organic chemicals or solvents. These disadvantages increase the cost of operation, increase the steps to obtain a useful cubic phase LLZO yield, and reduce the efficiency of the processes. Improvements in the efficiency, cost, or yield of methods for producing cubic LLZO is thus desired.

### SUMMARY

In one aspect, there is provided a method of producing LLZO having a cubic crystal phase comprising: providing an aqueous phase comprising zirconium (Zr) and lanthanum (La), the aqueous phase having a pH between 7 and 14; forming an intermediate comprising crystalline La(OH)₃ and amorphous Zr hydroxide from the Zr and the La in the aqueous phase; recovering and washing the intermediate to obtain a washed intermediate; and heat treating the washed intermediate with a Li precursor at a temperature of from 400 to 850° C. to obtain the LLZO. The LLZO obtained can have a size of between 50 nm to 1 μm.

In some embodiments the method according to the present disclosure, further comprises, before providing the aqueous phase, mixing a Zr precursor in the aqueous phase. The Zr precursor can be selected from the group consisting of Zr oxide, Zr nitrate, Zr oxy-nitrate, Zr chloride, Zr oxy-chloride, Zr sulfate, Zr oxy-sulfate and Zr acetate. In some embodiments the method according to the present disclosure, further comprises, before providing the aqueous phase, mixing a La precursor in the aqueous phase. The La precursor can be selected from the group consisting of La oxide, La nitrate, La chloride, La sulfate, and La acetate. Furthermore, the Li precursor can be selected from LiOH, LiNO₃, LiCl, LiBr, Li₂SO₄, lithium acetate, elementary Li, and Li₂O.

In further embodiments, the LLZO has a formula Li_{7±3}La_{3±3}Zr_{2±0.3}O_{12±0.3}. The LLZO may further comprise a dopant. The dopant may be selected from the group consisting of Ta, Nb, Al, Sn, Ge, Si, Li, Na, and K. Accordingly, in some embodiments the LLZO has a formula Li_{(7-x)±0.3}D_{y±0.3}La_{3±0.3}Zr_{2±0.3}O_{12±0.3} wherein 0 is the dopant and 0≤x≤3, 0≤y≤1.

In some embodiments, mixing comprises providing the La precursor in an excess amount over a stoichiometric ratio La:Zr=3:2 of up to 10%. In additional embodiment, the heat treating step comprises providing the Li precursor in an excess over a stoichiometric ratio Li:La:Zr=7:3:2 of from 0% to 200%.

In additional embodiments the method of the present disclosure further comprises, before providing the aqueous phase, mixing the Zr precursor and the La precursor then adjusting the pH of the aqueous phase to be between 7 to 14.

In yet additional embodiments the method of the present disclosure further comprises before providing the aqueous phase, providing a first aqueous phase comprising the Zr precursor and a second aqueous phase comprising the La precursor, adjusting the pH of the first aqueous phase and/or the second aqueous phase such that aqueous phase obtained from mixing the first aqueous phase and the second aqueous phase has a pH of between 7 to 14.

In the method of the present disclosure the pH may be between 8.5 and 10.5. The method may further comprise aging the intermediate, which can include holding a temperature of 4° C. to 270° C. for 2 h to 7 days. Furthermore, the washing can comprise using a solvent selected from the group consisting of water, isopropanol, ethanol, acetone and the mixture thereof.

In some embodiments, the steps of providing, forming, and recovering are performed in a controlled environment substantially free of CO₂.

Many further features and combinations thereof concerning the present improvements will appear to those skilled in the art following a reading of the instant disclosure.

### DESCRIPTION OF THE DRAWINGS

FIGS. 1A-F are electron microscopy images of intermediate phases of LLZO obtained according to one embodiment of the present disclosure; FIGS. 1A and 1D show hydrothermally aged hydroxide precipitates prepared at 270° C.; FIGS. 1B and 1E show ball-milled aged precipitates mixed with a stoichiometric LiOH amount; and FIGS. 1C and 1F show ball-milled aged precipitate after calcination at 240° C. for 6 h;

FIG. 2 shows X-ray diffraction (XRD) patterns (intensity as a function of 2e) of LLZO and intermediate species produced following calcination at temperatures of 250, 350, 400, 500, 600, and 800° C. (respectively the lines from the bottom to the top), with species LLZO (♦), La₂Zr₂O₇ (Δ) and La(OH)₃ (*) identified on the graph;

FIG. 3 shows X-ray diffraction (XRD) patterns (intensity as a function of 2e) of LLZO produced from solutions neutralized with NH₄OH to pH 8.6, aged at 240° C. for 3, 6 and 24 hours (respectively the lines from the bottom to the top) and calcined at 800° C. for 3 hours;

FIGS. 4A-F are electron microscopy images of primary and secondary LLZO particles according to one embodiment of the present disclosure;

FIG. 5A shows XRD patterns (intensity as a function of 2e) of LLZO samples prepared by calcination at 450° C. with variable amounts of excess Li from 1×, 2.5×, 5×, 7.5×, 10×−1, and 10× (respectively the lines from the bottom to the top), × is with respect to the dopant ([Al]) mole content (corresponding respectively to 5%, 12.5%, 25%, 36%, and 50% Li excess over the stoichiometric amount);

FIG. 5B shows XRD patterns (intensity as a function of 2e) of LLZO samples prepared by calcination at 600° C. with variable amounts of excess Li from 1×, 2.5×, 5×, 7.5×, and 10× (respectively the lines from the bottom to the top), where × is with respect to the dopant ([Al]) mole content (corresponding respectively to 5%, 12.5%, 25%, 36%, and 50% Li excess over the stoichiometric amount);

FIG. 5C shows XRD patterns (intensity as a function of 2e) of LLZO samples prepared by calcination at 800° C. with variable amounts of excess Li from 1×, 2.5×, 5×, 7.5×, and 10× (respectively the lines from the bottom to the top), where × is with respect to the dopant ([Al]) mole content (corresponding respectively to 5%, 12.5%, 25%, 36%, and 50% Li excess over the stoichiometric amount);

FIGS. 6A and 6B are electron microscopy images of LLZO pellets according to one embodiment of the present disclosure;

FIG. 7A is a graph of a temperature-dependent impedance analysis (imaginary impedance Im(Z) in function of real impedance Re(Z)) at temperatures of 27° C. (▪), 40° C. (●), 50° C. (▴), 60° C. (▾), 70° C. (♦), and 80° C. ( [symbol] );

FIG. 7B is an Arrhenius plot of the Ln (ionic conductivity) of LLZO in function of the inverse of the temperature;

FIGS. 8A-C shows XRD patterns (intensity as a function of 2e) of LLZO produced with LiOH as the Li precursor (FIG. 8A), Li₃NO₃ as the Li precursor (FIG. 8B), and Li₂O as the Li precursor (FIG. 8C), with the bottom lines corresponding to a calcination of 400° C., the middle lines a calcination of 600° C., and the top lines a calcination of 800° C.;

FIG. 9A shows XRD patterns (intensity as a function of 2e) of LLZO produced at calcination temperatures (for 6 h) of 300° C., 350° C., and 400° C. (respectively the lines from the bottom to the top);

FIG. 9B is an electron microscopy image of exemplary LLZO produced at a calcination temperature of 400° C. for 6 h;

FIGS. 10A-F show XRD patterns (intensity as a function of 2e) of LLZO, FIGS. 10A, 10B, 10C, 10D, and 10E respectively correspond to LLZO that was produced with variable excess Li over the stoichiometric amount; the excess Li is reported with respect to the dopant [Al], respectively 1×, 2.5×, 5×, 7.5×, to 10× (corresponding respectively to 5%, 12%, 25%, 36% and 50% Li excess) and was performed at calcination temperatures of 450° C., 600° C., and 800° C. (respectively bottom line to top line) for each of FIGS. 10A-10E; FIG. 10F summarizes the molar ratios of 1×, 2.5×, 5×, 7.5×, and 10× (respectively bottom line to top line) for the calcination temperature of 450° C.;

FIGS. 11A-C show XRD patterns (intensity as a function of 2e) of LLZO calcined at temperatures of 400° C., 600° C., 800° C., and 1050° C. (respectively the lines from the bottom to the top) with an aging step at a temperature of 150° C. (graph on the left), 200° C. (graph in the middle) and 240° C. (graph on the right);

FIG. 12 shows XRD patterns (intensity as a function of 2e) of LLZO products obtained by calcination of non-aged precipitates at temperatures of 450° C., 600° C., 800° C., and 850° C. (respectively the lines from the bottom to the top);

FIG. 13 shows XRD patterns (intensity as a function of 2e) of LLZO produced by calcination of non-aged precipitates that were subjected to different ball milling time: 30 min (top line) and 1 h (bottom line) at 650 rpm;

FIGS. 14A-B shows XRD patterns (intensity as a function of 2e) for calcined products obtained with solutions in which ZrCl₄ was substituted for ZnO(NO₃)₂, FIG. 14A shows the patterns of products obtained after washing of the precipitate and re-dispersion in LiOH solution prior to aging (at 200° C.), while FIG. 14B shows the patterns for the products not involving removal of chloride ions by washing prior to aging at 200° C., in both graphs, from bottom to top the lines the precipitates after aging, after calcination at 600° C., and after calcination at 800° C.; and

FIG. 15 shows an XRD patterns (intensity as a function of 2e) of LLZO produced by calcination at 600° C. without EDTA (bottom line) along the XRD patterns of non-LLZO products obtained by calcination at 600° C. in the presence of EDTA without H₂O₂ (middle line) and with H₂O₂ (top line).

### DETAILED DESCRIPTION

LLZO is an oxide-based garnet-type Li-ion conductor. The abbreviation LLZO as used herein refers to the lithium lanthanum zirconium oxide family with general chemical formula LiLaZrO (for example Li₇La₃Zr₂O₁₂), as well as variants of this formula (for example ±0.3, ±0.2, ±0.15 or ±0.1 in stoichiometry for each element), and/or the addition of at least one dopant element.

There is provided a scalable sustainable process of preparing an oxide-based Li-ion conductor that can be used as a solid electrolyte in Li-ion batteries, namely LLZO. The LLZO of the present disclosure can be mixed with other materials to form useful conductive composites for various electrical applications (for example batteries). The process of making LLZO comprises aqueous solution-based mixing of inorganic precursors (i.e. a source of La, and Zr) and a pH adjustment to induce hydrolysis; subjecting said hydrolyzed suspension to hydrothermal aging to form an intermediate precipitate containing La(OH)₃ crystals and amorphous Zr hydroxide; and subjecting said La(OH)₃-containing intermediate precipitate to heating at a temperature of up to 850° C. to obtain the LLZO.

As used herein, the term “precursor” or “source” when referring to an element, refers to a chemical compound that provides or releases said element in an aqueous solution, for example, a Li precursor can be LiOH.

In one embodiment, the formation of La(OH)₃ is performed during aging of the aqueous phase (i.e. hydrothermal processing). In a further embodiment, the step of heating to obtain the LLZO is a calcination. In yet a further embodiment, the LLZO obtained is nano- or micro-crystal having a primary particle size in the range of from about 50 nm to about 1 μm.

Conventionally, LLZO is prepared by a solid-state or sol-gel synthesis process that involves a high calcination temperature (>850° C.) combined often with high-energy milling and the use of toxic and expensive chemicals to facilitate crystallization. In contrast, the method according to the present disclosure forms the cubic phase LLZO crystals at temperatures of up to 850° C. Furthermore, in conventional methods (such as solid-state or sol-gel) in order to obtain cubic phase-pure LLZO, the methods require to repeat the milling-calcination cycle several times. As such conventional processes are time and energy consuming, thus costly.

On the other hand, in one embodiment, the process according to the present disclosure, produces cubic phase LLZO crystals with a single heating cycle (such as a calcination). Thus, the energy required to operate the present method is significantly reduced when compared to conventional methods.

The tetragonal form of LLZO does not typically provide a useful conductivity for electric applications (such as batteries). Furthermore, the contamination of tetragonal LLZO in cubic phase LLZO reduces the conductivity of the cubic phase LLZO.

The method according to the present disclosure, produces LLZO in its cubic crystalline form which is a ceramic material useful in the manufacture of solid-state electrolytes for batteries. Indeed, in one embodiment, the LLZO produced with the present methods has a conductivity of from 10⁻⁴ to 10⁻³ S/cm at room temperature (defined as between 10 to 30° C.).

Accordingly, in one embodiment, the LLZO according to the present disclosure is substantially free of tetragonal LLZO. In one embodiment, the LLZO contains less than 10 wt. %, less than 5 wt. %, less than 3 wt. %, or less than 1 wt. % of LLZO tetragonal phase crystals. In some embodiments, these low or negligible LLZO tetragonal phase crystal concentrations are achieved following a single heat treatment cycle according to the present method (such as a calcination). The crystal structure of the LLZO can be assessed by methods known in the art such as a X-ray diffraction (XRD) analysis. The percentage of each crystalline form (tetragonal or cubic) can also be quantified with XRD.

In one embodiment, the LLZO according to the present disclosure comprises nanocrystals that have a primary particle size of from about 50 nm to about 1 μm. The term “primary particle” is defined herein as a single crystal unit not bound to another crystal unit. The term “secondary particle” is defined herein as the agglomeration of two or more crystal units. The term “size” as used herein refers to the quasi-spherical diameter of the crystal. Without wishing to be bound by theory, the resulting size of the primary particles of the cubic phase crystals depends on the heat treatment temperature (for example calcination temperature). The lower the heat treatment temperature the smaller the particle size obtained. For example, treatment temperatures of about 400° C. result in a size in the range of 50 nm and treatment temperatures in the range of 800° C. result in a size closer to 1 μm.

In some embodiments, the LLZO has the chemical composition of Li₇₋ₓD_{y}La₃Zr₂O₁₂, where D refers to a dopant, and the ranges of x and y are 0≤x≤3, 0≤y≤1, respectively, with the stoichiometry being variable to the degree of ±0.3, ±0.2, ±0.15 or ±0.1. In one embodiment, the dopant is selected from the group consisting of Ta, Nb, Al, Sn, Ge, Si, Li, Na, K and combinations thereof. In one example, the dopant is Al.

The chemical precursors of La and Zr are first mixed in an aqueous phase. In one embodiment the precursors are La salts and Zr salts. In one embodiment the La precursor is selected from the group consisting of La oxide, La nitrate, La chloride, La sulfate, and La acetate. In one embodiment, the Zr precursor is selected from the group consisting of Zr oxide, Zr nitrate, Zr oxy-nitrate, Zr chloride or oxy-chloride, Zr sulfate or oxy-sulfate and Zr acetate. In some embodiments, the Zr precursor is Zr nitrate and/or Zr oxy-nitrate salts as these two salts yield cubic-structured garnet essentially impurity-free at relatively lower calcination temperature, such as at or below 600° C.

In one embodiment, the aqueous phase can be a solution or a colloidal suspension where the solvent is water. Water is an advantageous medium since it is readily available, low cost, and is safe in contrast to the toxic organic solvents from sol-gel methods. A transparent solution can be obtained using acids; whereas a colloidal suspension is the result of neutralization of metallic element-containing solution with alkaline reagents (hydrolysis). Thus, in one example the colloidal particles consist of metal hydroxides. In one embodiment, the Li, La, Zr, and dopant (e.g. Al) precursors are inorganic. In one embodiment, during mixing, only inorganic chemicals and the aqueous phase are used. In some embodiments, the aqueous phase is free of organic additions, such as ethylenediaminetetraacetic acid (EDTA).

In one embodiment the pH of the acidic solution containing the dissolved La and Zr precursors is adjusted by using an alkaline reagent to the range 7 to 14, or 8.5 to 10.5 in order to induce colloidal metal hydroxide formation prior to the hydrothermal aging treatment. The alkaline reagent may be selected among LiOH, NaOH or NH₄OH bases and used in powder form or as alkaline solution by prior dissolving into water. In a preferred embodiment a LiOH alkaline solution is made by dissolving LiOH·H₂O into water and mixing it with the precursor acidic solution.

In some embodiments, the preparation of the aqueous precursor solution may be done by adding/dissolving the La and Zr precursor salts together and after adjusting the pH or can be done sequentially by preparing separate La and Zr solutions, adjusting their pH, and afterwards mixing them and further adjusting the pH. Solution preparation and pH adjustment may involve agitation for better mixing and reaction efficiency.

In one embodiment, the concentration of La could be over stoichiometric in order to compensate the solubility limits in the pH range of less than 10. For example, if there are no additives the over-stoichiometric ratio at pH˜8 is La:Zr=3.015:2. In some embodiments the ratio of La:Zr=3±0.2:2±0.2, La:Zr=3±0.15:2±0.15, or La:Zr=3±0.1:2±0.1. Above a pH of 10, excess La is not necessary because of the solubility of La(OH)₃ in aqueous phases is a function of the pH. Accordingly, above a pH of 10 at room temperature, substantially all of La(OH)₃ in the aqueous phase precipitates. However, the solubility also varies with the temperature. Thus the methods according to the present disclosure are not limited to providing excess La, particularly in embodiments where the pH and temperature are such that substantially all of the La(OH)₃ precipitates.

In one embodiment, the concentration of lanthanum (i.e., [La]) in the aqueous phase resulting from the mixing is in the range from about 0.001 to about 10 M, from about 0.1 to about 3 M or from 0.5 to 1.5 M. Meanwhile Zr (e.g. as salt) is added to the La containing aqueous phase to a concentration corresponding to about their stoichiometric molar ratio (i.e. ±5%, 4%, 3%, ±2% or ±1%), namely La:Zr=3:2. In one example, the stoichiometric ratio La:Zr=3:2 translates to [Zr]=0.67 M for [La]=1 M. La may be added in small excess over the 3:2 La:Zr molar ratio if the pH is <10, such as up to 0.5%, up to 1%, up to 3% or up to 10% (i.e. La:Zr=3.015, 3.03, 3.1, or 3.3; the excess amount increasing with decreasing pH). Finally, a dopant like Al is optionally added to the solution prior to pH adjustment as in this molar ratio: La:Zr:Al=3.:2:y, where 0≤y≤1.

In one embodiment, the LLZO further comprises one or more dopant species. In one embodiment, the dopants are metallic elements. In a further embodiment, the dopant is selected from Al, Ta, Nb, Sn, Si, Li, Na added as inorganic salts, for example nitrate, chloride, sulfate or acetate salts to the precursor solution. In embodiments where dopants are included, the LLZO may have a stoichiometry of Li₇₋ₓD_{y}La₃Zr₂O₁₂, where D is the dopant and 0≤x≤3, 0≤y≤1. The dopants can be included to improve the electrical conductivity of the resulting LLZO by stabilizing the cubic phase. In one embodiment, Al, added as Al(NO₃)₃·9H₂O is a particularly effective dopant that is favored due to its low cost and abundance.

The aqueous phase obtained after mixing is allowed to form the intermediate which comprises La(OH)₃ and Zr oxide by increasing the pH to at least 7, at least 8 or between 8 to 11. The maximal pH may be determined by the saturation concentration of the alkaline source (for example in the case of [LiOH]=ca. 5.3 M, the corresponding maximal pH is 11). The pH can be increased by stepwise addition of the aqueous phase into an alkaline solution or the opposite adding the alkaline solution to the acidic precursor metal containing solution. The alkaline solution can for example be LiOH, NaOH, NH₄OH or KOH. The formation of La(OH)₃ as part of the intermediate species is necessary for the subsequent formation of cubic crystalline LLZO upon calcination at relatively low temperature (<850° C.). Furthermore, it is desirable to limit, reduce, or eliminate the presence of CO₂ as it may lead to the formation of La(OH)CO₃. Formation of La(OH)CO₃ will compromise the efficacy of the process as it reduces the yield of cubic phase LLZO, promoting instead the formation of the undesirable tetragonal phase LLZO making calcination temperatures above 850° C. necessary. In one embodiment, the intermediate is substantially free of La(OH)CO₃. In one embodiment, the intermediate comprises less than 10%, less than 5%, less than 3% or less than 1% of La(OH)CO₃. The crystalline intermediate La(OH)₃, depending on the forming conditions, has a size in the range of from 20 nm to 20 μm. La(OH)₃ has an anisotropic, rod-like morphology.

In one embodiment, the aqueous phase obtained after mixing and pH adjustment step is subjected to aging. Although aging is not necessary for the formation of La(OH)₃ crystals mixed with amorphous Zr/Al hydroxide which do form by precipitation induced by the pH adjustment, the hydrothermal aging helps increase the degree of crystallinity of La(OH)₃. The aqueous phase may be aged in a controlled environment such as an air-free chamber or a glovebox, to avoid CO₂ presence or may be pretreated prior to aging to remove any dissolved CO₂ using for example nitrogen sparging. The aging process can be conducted at a target temperature of from about 4° C. to about 270° C., for 0 to about 7 days. For example, the duration of aging can be from 0 second (i.e., as prepared after solution-based mixing and pH adjustment or no aging) to several hours (such as 2 to 4 hours). Unless specified otherwise, the duration recited with respect to the aging step (e.g. 3 hours) refers to the holding time. The holding time, is the period of time at which the target temperature is maintained. In one example, the aging protocol comprises or consists of (1) ramping from room temperature to 150° C. within 1.5 hrs; (2) then holding the temperature at 150° C. for 3 hrs; and (3) after aging, letting reactor contents cool down naturally or quenching in water (for ˜30 mins) to accelerate cool down. The aging process can be conducted with or without agitation. In one embodiment, the agitation rate is from 0 to about 1000 rpm, or from about 100 to about 1000 rpm.

In one embodiment where no hydrothermal aging is performed but the solution has a temperature above 30° C. after the pH adjustment step, the aqueous phase is filtered to recover the intermediate comprising La(OH)₃ and the precipitate washed in a controlled environment. In embodiments where no aging is performed, it is required to control the environment from the introduction of La to before the calcination, to be substantially free of CO₂. In such embodiments, a centrifugation can be performed to recover the intermediate. In embodiments where aging is performed, it is preferable to also maintain the aqueous phase, the pH adjustment and the aging in a controlled environment that is substantially free of CO₂. In one embodiment, the controlled environment, has less than 5%, less than 3%, or less than 1% of CO₂ by volume. In some embodiments, the steps of the method of the present disclosure, once La is provided and until the heat treatment is performed, are done in the controlled environment.

Prior to calcination, the precipitate containing intermediate La(OH)₃ is washed thoroughly whether the aging step is performed or not, in order to remove the anions or the additives (if any are added). In one embodiment, the washing comprises rinsing the precipitate with a solvent. The solvent for washing can be selected from water, isopropanol, ethanol or any other alcohol (<C₆ alcohol), and acetone or a mixture thereof. In one embodiment, water is the preferred solvent for washing.

After washing, a Li precursor is added to the intermediate. In one embodiment, the washed intermediate obtained as a precipitate is mixed with the Li precursor. Mixing is performed to ensure good homogeneity and consistency in LLZO quality. In one embodiment, the Li precursor is a Li compound. In one embodiment the Li precursor is selected from the group consisting of LiOH, LiNO₃, LiCl, LiBr, Li₂SO₄, lithium acetate, elementary Li (i.e., Li metal), and Li₂O. This mixing process can be done mechanically for improved homogenization. In one embodiment, the mechanical mixing can be performed via ball milling or other suitable powder mixing equipment. In one example, the rotation spend of ball milling is in the range from 0 to 700 rpm, and depending on the technique and equipment used for milling, the protocol for ball milling can be either continuous or step-wise. For instance, one commonly used ball-milling protocol is ball milling with 1 mm-ZrO₂ media, in a ZrO₂ jar, at 650 rpm, for 10 cycles of 3-min grinding/7-min resting. Thus, in this example, ball milling is 30 mins in total.

The Li precursor Li₂CO₃ is not suitable for the methods of the present disclosure as the carbonate could contaminate the intermediate precipitate that contains the La(OH)₃ crystals. When a CO₂/CO₃ contamination occurs and particularly when La(OH)CO₃ is formed, the thermal treatment (calcination) temperature needed to obtain cubic phase LLZO becomes much higher, such as 1000-1200° C., and more than one treatment cycle may be required. Accordingly, in some embodiments, the precursors of the present disclosure are not carbonate precursors.

The intermediate precipitate is mixed with Li precursors in at least as much as per the stoichiometric ratio of Li₇La₃Zr₂O₁₂ or Li₇₋ₓD_{y}La₃Zr₂O₁₂ (where x and y are 0≤x≤3 and 0≤y≤1 respectively), in embodiments where a dopant D is included. The stoichiometric ratio, is therefore Li:La:Zr=7:3:2 or (7-x):3:2. In some embodiments, the excess Li can be defined as a percentage of excess over the stoichiometric ratio. For example, a 10% excess over the stoichiometric ratio can be expressed as 7+10%:3:2 which is equivalent to 7.7:3:2. In another example, a 10% excess over the stoichiometric ratio in the presence of a dopant is expressed as (7-x)+10%:3:2. In some embodiments, the excess over the stoichiometric ratio of Li is 0% (no excess), at least 1%, at least 5%, at least 10%, at least 100%, or up to 200%. For example, the excess over the stoichiometric ratio can be from 0% to 200%, from 1% to 200%, from 0% to 100%, from 1% to 200%, from 5% to 100%, or from 10% to 50%. In a non-limitative example, in the case of Li_{6.1}Al_{0.3}La₃Zr₂O₁₂ an excess value for Li of 36% has been found to be optimal.

Excess amounts of Li can be advantageous to compensate the Li loss during calcination, particularly at the higher end of the heat treatment range i.e. around 800° C. Furthermore, without wishing to be bound by theory, an excessive amount of Li can also help to enhance the activity of Li in driving the LLZO cubic phase formation as opposed to the tetragonal phase. Furthermore, without wishing to be bound by theory, an excessive amount of Li can also help to enhance the activity of Li in driving the LLZO cubic phase formation at relatively low calcination temperature (e.g. 400° C.). The excess quantity can vary depending on the preparation of the intermediate precipitates. For example, the aging temperature, ball milling condition or even the selection of Li sources are all factors that can affect the optimal quantity of excess Li.

The LLZO is formed under a heat treatment temperature of no more than about 850° C. In one embodiment, the heat treatment is a calcination. In one embodiment, the temperature is up to about 850° C., up to about 825° C., up to about 800° C., up to about 775° C., up to about 750° C., up to about 700° C., or up to about 600° C. In a further embodiment, the temperature is between about 250° C. to about 850° C., between about 300° C. to about 850° C., between about 350° C. to about 850° C., between about 400° C. to about 850° C., between about 250° C. to about 800° C., between about 350° C. to about 800° C., between 400° C. to about 800° C., between about 400° C. to about 600° C., or between about 500° C. to about 600° C.

In one embodiment, the protocol for the heat treatment comprises (1) ramping (2) holding and (3) cooling. The specified treatment temperature and time, unless specified otherwise, correspond to the holding stage. In one embodiment, the holding stage lasts from about 3 hours to about 12 hours. In one example, the ramping is performed at 5° C./min from room temperature until the holding temperature is reached, then holding for 6 hrs, and after holding, naturally cooling in the oven. The cooling process can either be natural cooling (i.e. without any external cooling means) or with cooling means such as quenching. Although there is no special requirement in the atmosphere during the heat treatment, in some embodiments a CO₂-free gas is used for the atmosphere to limit the formation of carbon containing impurities.

In one embodiment, after the heat treatment, depending on the desired application for the LLZO, the LLZO can further be processed to produce densified products such as pellet types by compression and sintering or densified tapes, films or separators. Alternatively LLZO powders may be deposited by wet-chemical methods followed by sintering to form porous ceramic films. There are many commercial applications for cubic phase LLZO, some examples are provided in Balaish, M., Gonzalez-Rosillo, J. C., Kim, K. J. et al. Processing thin but robust electrolytes for solid-state batteries. Nat Energy 6, 227-239 (2021), which is incorporated herein by reference. In one example, densified pellets are made by a compression and sintering treatment of between 5 to 7 hours at a temperature of between 1000 to 1200° C. In other examples LLZO powder is made in porous films via wet chemical deposition methods, including screen printing, doctor blade, spin coating, spray pyrolysis, followed by sintering/annealing at lower temperatures such as 400 to 900° C.

A non-limiting exemplary method of preparing LLZO is as follows. A mixed aqueous solution composed of ZrO(NO₃), La(NO₃)₃·6H₂O and Al(NO₃)₃·9H₂O in the stoichiometric ratio of La:Zr:Al=3.0154:2:0.3 was prepared. The pH value was about 0.5. The prepared solution was then dropwise added into a diluted LiOH solution. After this neutralization, the final pH value reached 8.5. The resultant hydrolysed suspension was then directly transferred to a 100 mL autoclave with the designated concentration (e.g. total [La]=1 M regardless if it's in precipitate or supernatant), which was then heated to 150° C. for 3 hours including ramping and holding. After aging at 150° C. for 3 hours without agitation, the wet precipitate was recovered via centrifugation and washed with water and isopropanol thoroughly. The recovered precipitate was then mixed with a designated quantity of LiOH by ball milling with 1 mm ZrO₂ balls at 650 rpm for 10 cycles that involved 3 min grinding/7 min resting. The Li was added in excess as x times with respect to [Al]. The [Al] corresponded to the stoichiometry of Li_{6.1}Al_{0.3}La₃Zr₂O₁₂; the x value varied from 1 to 10, which corresponds to 5% to 50% excess Li with reference to the stoichiometric amount of Li. Finally, the ground suspension was separated from the grinding media and dried at 80° C. under vacuum. The completely dry precipitate was then calcinated at the temperature from 450 to 800° C. for 6 hours to form LLZO cubic phase nanocrystals.

In an alternative exemplary method, an La—Al precursor solution is prepared first by dissolving La(NO₃)₃·6H₂O and Al(NO₃)₃·9H₂O in water and adding into it LiOH·H₂O in the stoichiometric ratio Li:La:Al=6.1:3.0154:0.3 (resulting pH about 7.8). Separately the Zr solution is prepared by dissolving ZrO(NO₃) into water (resulting pH about 0.2). The Zr solution is then dropwise added into La—Al—Li solution at a molar ratio La:Zr:Al=3.0154:2:0.3. The resultant mixed solution has a pH˜6. Subsequently, the pH is adjusted to a value between 7.5 to 11 or preferably between 8.5 to 10.5. The resultant hydrolyzed suspension is then directly transferred to a 450-mL autoclave with the designated concentration (e.g. total [La]=1 M regardless if it's in precipitate or supernatant), which is then heated to 200° C. for 3 hours including ramping and holding. After aging at 200° C. for 3 hours with agitation, the wet precipitate is recovered via centrifugation and washed with water and isopropanol thoroughly. The recovered precipitate is then mixed with a designated quantity (excess [Li] for calcination is 7.5 times with respect to [Al] or 36% excess Li over the stoichiometric amount corresponding the following formula: Li_{6.1}Al₀₃La₃Zr₂O₁₂.

The method according to the present disclosure is a direct preparation of nano and sub-micron cubic phase crystals (50 nm-1 μm) of oxide-based garnet-type Li-ion conductor, more specifically LLZO. The present wet-chemical process (starting with aqueous mixing) is drastically different from the most typical route of solid-state or sol-gel reactions according to the prior art. Furthermore, in some embodiments, only inorganic precursors and water are used, which makes this process distinct from known processes that are generally characterized by the presence of organic species. The present process requires much less processing time compared to the sol-gel or solid-state methods because it eliminates the tetragonal-to-cubic phase transformation processing steps consisting of several cycles of homogenizing/grinding and calcination. Using solution-prepared precursor mixed metal (containing crystalline) La(OH)₃ hydroxide precipitates at targeted pH range with or without hydrothermal aging, the required calcination temperature for producing cubic LLZO can be significantly reduced (i.e. below 850° C.). In other words, the present process is more energy-efficient. Additionally the method owing to the nature of the precursor and lower calcination temperature yields nanocrystals of LLZO which in turn can be processed much easier and at significantly reduced forming and sintering temperature (i.e. below 1000° C.) during device fabrication for solid-state battery applications. Furthermore, the yield of the present method is improved compared to other known wet-chemical processes because in the present process a high concentration of precursors are used. Moreover, unlike other solid-state reaction routes where extensive high-energy ball milling is mandatory, the ball milling in the method of the present disclosure is optional and would only be performed for a relatively short time compared to the solid-state reaction requirement. Consequently, the present method and LLZO nanocrystal material has the advantages of sustainability, simplicity, versatility and efficiency.

The obtained LLZO from the methods of the present disclosure is preferentially stored in protective atmosphere, which must be CO₂-free. Dry (i.e., de-moisture) environment is also recommended.

### Example 1: Synthesis of LLZO Using NH₄OH as Alkaline Reagent in Adjusting pH

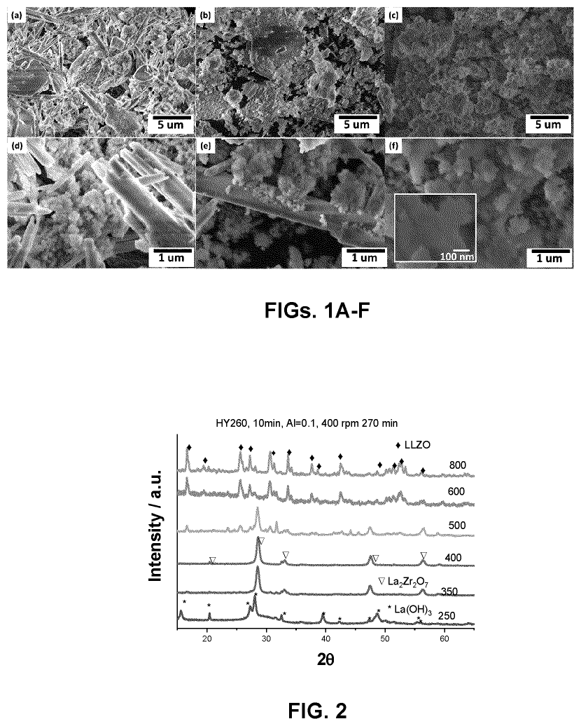

Referring to FIGS. 1A-F, SEM images are provided at various stages of the present method. FIG. 1A and FIG. 1D were obtained after the aging step. The aged precipitates were prepared by pH adjustment to 8.5 of an initial mixture containing La, Zr and Al in the stoichiometric ratio La:Zr:Al of 3.0154:2:0.1 in solution ([La]=0.1 M) with NH₄OH as the base. A hydrothermal aging was performed at 270° C. for 10 min with an agitation of 300 rpm. FIG. 1B and FIG. 1E show the intermediate aged precipitates after ball milling at 650 rpm with LiOH in isopropanol for a total of 30 min with 3 min milling/7 min resting protocol. FIG. 1C and FIG. 1F show the dry ball-milled precipitates after calcination at 240° C. for 6 hours, where the zoom in FIG. 1 shows that the primary quasi-spherical particle size of the calcined precipitate has a diameter of about 50 nm.

FIG. 2 shows the X-ray diffraction (XRD) patterns of LLZO materials obtained by calcination of hydrothermally aged precipitates at different calcination temperatures for 6 hours (250, 350, 400, 500, 600 and 800° C.). Hydrothermally aged precipitates were obtained from mixed (La:Zr:Al=3.0154:2:0.1) solutions ([La]=0.1 M) neutralized to pH 8.5 with NH₄OH and aged at 260° C. for 10 min). Prior to calcination the precipitates were mixed with a stoichiometric amount of LiOH (Li:La=6.1:3) and ball milled for 4.5 hours at 400 rpm in 6 cycles (45 min/15 min rest). Upon calcination, the crystalline phase La(OH)₃ in the aged precipitate (present at 250° C.) decomposed and reacted with amorphous Zr-containing precipitate to form the intermediate phase La₂Zr₂O₇ at 350° C. La₂Zr₂O₇ subsequently reacted with LiOH at 500° C. or above, leading to the formation of LLZO at and above 600° C.

Without wishing to be bound by theory a likely transformation pathway leading to crystalline LLZO formation (dopant-free LLZO case given as example) is:
La(OH)₃+amorphous Li—La—Zr containing precipitate

$$\begin{matrix}{above ca . 250 ° C}^{⟶} . - \to & {La}_{2} {Zr}_{2} {O}_{7} + amorphous Li species \\ {above ca . 400 ° C .}^{⟶} & {Li}_{7} {La}_{3} {Zr}_{2} {O}_{12}\end{matrix}$$

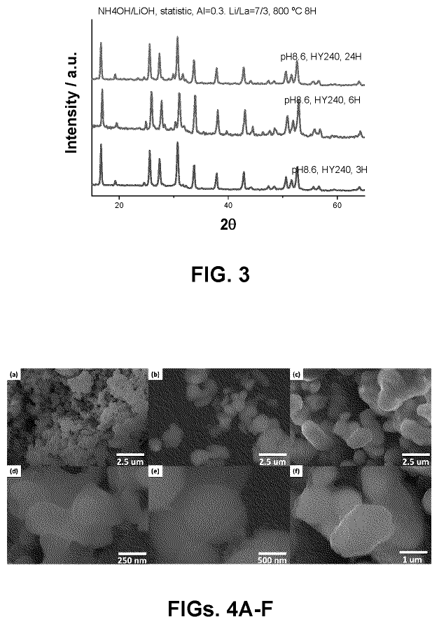

In another synthesis test, a mixed aqueous solution composed of ZrO(NO₃), La(NO₃)₃·6H₂O and Al(NO₃)₃·9H₂O in the stoichiometric ratio of La:Zr:Al=3.0154:2:0.3 was prepared. The pH value was about 0.5. The prepared solution was then dropwise added into diluted NH₄OH solution. After this neutralization, the final pH value reached 8.5. The suspension was then directly transferred to an 100-mL autoclave with the designated concentration (e.g. total [La]=0.1 M regardless if it's in precipitate or supernatant), which was then aged at 240° C. for 3, 6 or 24 hours, the wet precipitate was recovered via centrifugation and washed with water and isopropanol thoroughly. The recovered precipitate was then mixed with a stoichiometric quantity of LiOH manually (no ball milling). Finally, the ground mixture was separated from the grinding media and dried at 80° C. under vacuum. The completely dry precipitate was then calcinated at 800° C. for 8 hours to obtain LLZO nanocrystals. FIG. 3 shows the XRD pattern of LLZO nanocrystals prepared with NH₄OH during solution-based mixing. Regardless of the aging time, pure cubic LLZO was obtained after 800° C. calcination.

### Example 2: Synthesis of High-Conductivity Cubic LLZO Nanocrystals

In this example LLZO is synthesized and then characterized in terms of crystal phase, morphology and ionic conductivity. FIGS. 4A-F show LLZO crystals obtained according the protocol involving: precipitates prepared using aqueous-based aging at 150° C. for 3 hours with [La]:[Zr]:[Al]=3:2:0.3 M. The precipitates were then ball milled at 650 rpm with targeted LiOH amount in isopropanol for totally 30 min with 3 min milling/7 min resting protocol. The targeted LiOH quantity was the summation of stoichiometric Li plus additional ones in the quantity of 10 times higher than the dopant [Al]. The [Al] corresponds to the stoichiometry of Li_{6.1}Al_{0.3}La₃Zr₂O₁₂. Finally the milled precipitate was thermally converted into LLZO at 450° C. (FIGS. 4A and 4D), 600° C. (FIGS. 4B and 4E) and (FIGS. 4C and 4F) 800° C. for 6 hours.

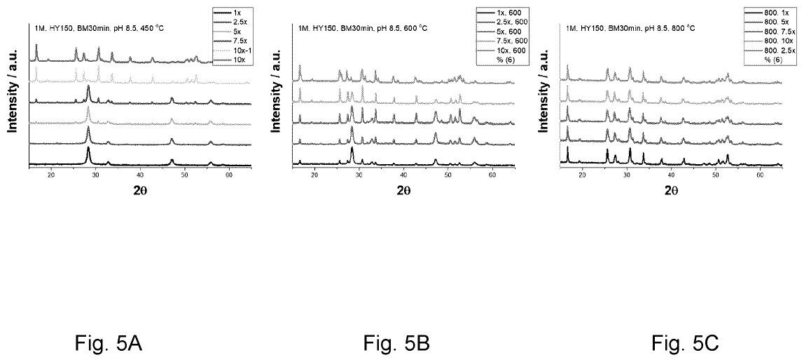

Referring to FIGS. 5A-C, the XRD patterns of the LLZO nanocrystals obtained show that crystalline cubic garnet LLZO was obtained at as low a temperature as 450° C. (FIG. 5A). The patterns of LLZO prepared using variable amounts of excess Li over the stoichiometric amount (the excess amount is defined in terms of the dopant [Al] level from 1× (bottom line) to 10× (top line) of [Al] corresponding to 5% and 50% excess Li respectively) are provided for comparison. It is clear that crystallization is favoured with some amount of excess Li, e.g. 10 times (50%) at 450° C. (FIG. 5A) and 7.5 times (36%) at 600° C. (FIG. 5B).

The secondary particle size was determined to vary in the range from about 200 nm to about 5 μm, corresponding to a calcination temperature of from 400 to 800° C., respectively. And the primary particle size was determined to be of from 50 nm to 1 μm also for a calcination temperature of from 400 to 800° C. respectively. These results demonstrated the existence of agglomeration among LLZO nanocrystals.

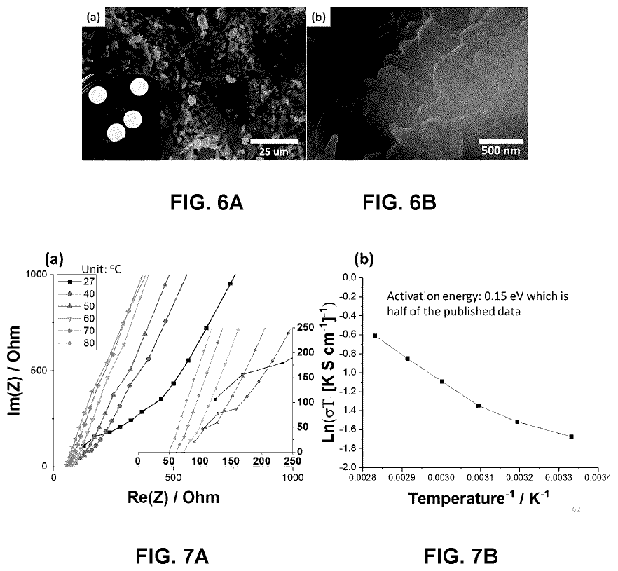

FIGS. 6A and 6B show SEM images of the microstructure of pellets (inset photo in FIG. 6A) made from LLZO crystals produced according the protocol described in the present Example 2 above with Li excess of 5% excess over the stoichiometric amount and a calcination at 600° C. The produced LLZO powders were pressed into pellets that had size of 12.5 mm in diameter, 0.69 mm in thickness after sintering at 1200° C. for 6 hours.

Making reference to FIGS. 7A and 7B, FIG. 7A shows a temperature-dependent impedance analysis of one of the LLZO pellets. Conductivity measurements were collected from 27° C. to 80° C. using a Au/LLZO/Au symmetrical cell. The LLZO particular pellet used was annealed at 1200° C. for 12 hours and had 11.8 mm in diameter and 0.8 mm in thickness. FIG. 7B shows the Arrhenius plot of the corresponding ionic conductivity. At room temperature, the conductivity was determined to be about 6×10⁻⁴ S/cm. This conductivity value is consistent with desirable industry standards.

The precipitate prepared using aqueous-based aging at 150° C. for 3 hours with [La]:[Zr]:[Al]=3:2:0.3 M was selected to make LLZO crystals. The precipitate was then ball milled at 650 rpm with targeted LiOH amount in isopropanol for totally 30 min with 3 min milling/7 min resting protocol. The targeted LiOH quantity was the summation of stoichiometric Li plus an excess amount corresponding to 10 times the dopant [Al] (which translates to ˜50% excess over the stoichiometric Li amount) in Li_{6.1}Al_{0.3}La₃Zr₂O₁₂. Finally the milled precipitate/LiOH mixture was thermally converted into LLZO at 600° C. for 6 hours. The grain size growth was not significant in our prepared LLZO at a temperature of 600° C., determined to be about 60 nm upon analysis of XRD data.

### Example 3: Effect of Different Li Precursors

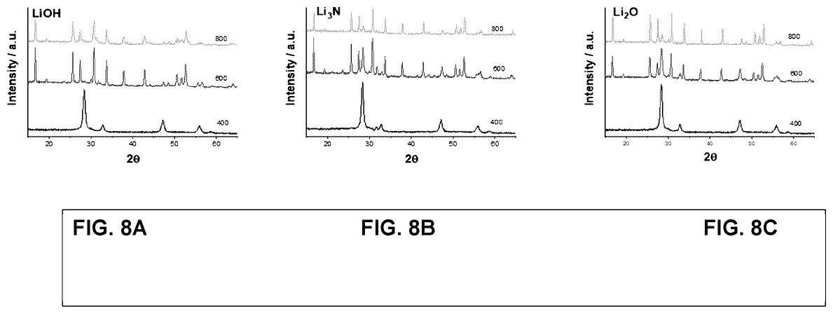

A mixed aqueous solution composed of ZrO(NO₃), La(NO₃)₃·6H₂O and Al(NO₃)₃·9H₂O in the stoichiometric ratio of La:Zr:Al=3.0154:2:0.3 was prepared. The pH value was about 0.5. The prepared solution was then dropwise added into diluted LiOH solution. After this neutralization, the final pH value reached 8.5. This suspension was then directly transferred to a 100-mL autoclave with the designated concentration (e.g. total [La]=1 M regardless it's in precipitate or supernatant), which was then heated to 150° C. for 3 hours including ramping and holding. After aging at 150° C. for 3 hours, the wet precipitate was recovered via centrifugation and washed with water and isopropanol thoroughly. The recovered precipitate was then mixed with designated quantity of LiOH manually. Excess [Li] amount for calcination is 1 time higher with respect to [Al] (or 5% excess over the stoichiometric amount of Li). The [Al] corresponds to the stoichiometry of Li_{6.1} Al_{0.3}La₃Zr₂O₁₂). Finally, the ground mixture was separated from the grinding media and dried at 80° C. under vacuum. Another sample was prepared with the same conditions except the LiOH used in calcination was substituted with Li₃NO₃ (shown as Li₃N in FIG. 8B). A third sample was prepared with the same conditions except the LiOH used in calcination was substituted with Li₂O The completely dried precipitate/Li source mixtures were then calcined at from 400 to 800° C. for 6 hours to obtain LLZO nanocrystals.

FIGS. 8A-C show the respective XRD patterns of the LLZO nanocrystals prepared (FIG. 8A for LiOH, FIG. 8B for Li₃NO₃ and FIG. 8C for Li₂O). It can be seen that LLZO to have formed only at 600 and 800° C. Among all candidates of Li sources, LiOH and Li₃NO₃ provided LLZO with higher XRD peak intensity at 600° C. as opposed to Li₂O that required a higher calcination temperature, i.e. 800° C.

In another test Li metal as the Li precursor was evaluated. A mixed aqueous solution composed of ZrO(NO₃), La(NO₃)₃·6H₂O and Al(NO₃)₃·9H₂O in the stoichiometric ratio of La:Zr:Al=3.0154:2:0.3 was prepared. The pH value was about 0.5. The prepared solution was then dropwise added into diluted LiOH solution. After this neutralization, the final pH value reached 8.5. This suspension was then directly transferred to a 225-mL autoclave with the designated concentration (e.g. total [La]=0.1 M regardless it's in precipitate or supernatant), which was then heated to 220° C. for 30 mins of holding, with agitation at 300 rpm. After aging at 220° C. for 30 mins, the wet precipitate was recovered via centrifugation and washed with water and isopropanol thoroughly, and then ball milled at 400 rpm for 6 cycles consisting of 45 mins grinding/15 mins resting. The recovered precipitate was then mixed manually with designated quantity of Li metal pre-heated in air at 350° C. for 6 hours (10 times higher than the stoichiometry of needed Li). Finally, the mixture was separated from the grinding media and dried at 80° C. under vacuum. The completely dry precipitate/Li metal mixture was then calcinated at from 300 to 400° C. for 6 hours to obtain LLZO nanocrystals.

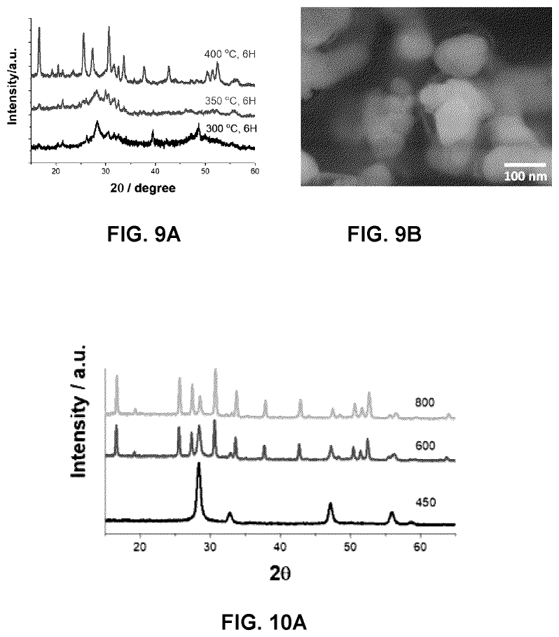

FIG. 9A shows the XRD patterns of the LLZO materials obtained after calcination (for 6 hours) of aged precipitates in the presence of pre-heated Li metal. LLZO crystals (shown in FIG. 9B) in this case formed at as low temperature as 400° C. The pre-heated Li metal consisted of LiOH, Li₂CO₃, Li₂O and Li₃N.

### Example 4: Effect of Excess Li at Different Calcination Temperatures

A mixed aqueous solution composed of ZrO(NO₃), La(NO₃)₃·6H₂O and Al(NO₃)₃·9H₂O in the stoichiometric ratio of La:Zr:Al=3.0154:2:0.3 was prepared. The pH value was about 0.5. The prepared solution was then dropwise added into diluted LiOH solution. After this neutralization, the final pH value reached 8.5. This suspension was then directly transferred to an 100-mL autoclave with the designated concentration (e.g. total [La]=0.5 M regardless it's in precipitate or supernatant), which was then heated to 220° C. for 3 hours including ramping and holding. After aging at 220° C. for 3 hours without agitation, the wet precipitate was recovered via centrifugation and washed with water and isopropanol thoroughly. The recovered precipitate was then mixed with variable quantity of excess LiOH by ball milling with 1 mm ZrO₂ balls at 650 rpm for 10 cycles that involves 3 min grinding/7 min resting. The excess [Li] was varied from 1× to 10× with respect to [Al]. The [Al] corresponds to the stoichiometry of Li_{6.1}Al_{0.3}La₃Zr₂O₁₂. In terms of percent excess the equivalent numbers approximately are: 5% for 1×, 12% for 2.5×, 24% for 5×, 36% for 7.5× and 50% for 10× over the stoichiometric Li amount. Finally, the ground mixture was separated from the grinding media and dried at 80° C. under vacuum. The completely dry precipitate/LiOH mixture was then calcinated at the temperature from 450 to 1050° C. for 6 hours to produce LLZO crystals.

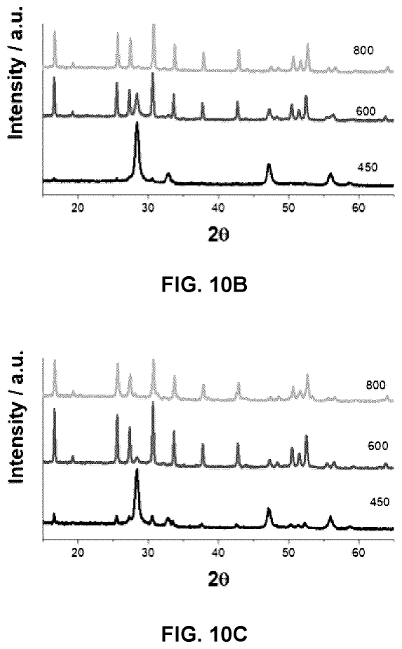

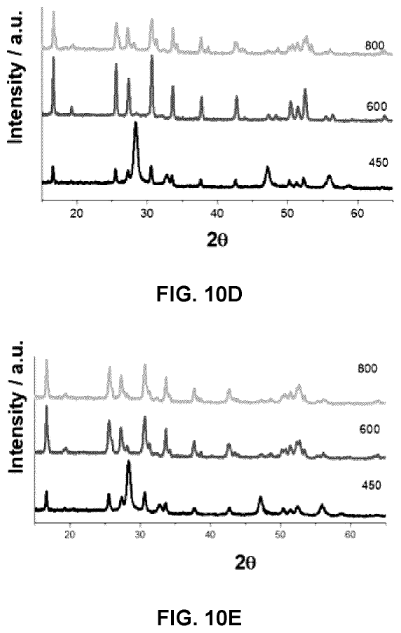

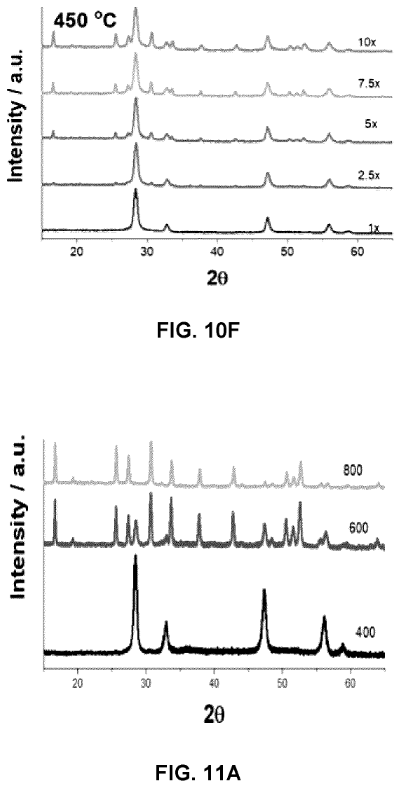

FIGS. 10A-F show the XRD patterns of LLZO nanocrystals prepared with the different amounts of excess Li (as LiOH), respectively 1×, 2.5×, 5×, 7.5×, 10×, at different calcination temperatures. Excess Li is important to promote the formation of crystalline cubic LLZO at low temperature. This is demonstrated by the XRD data in FIG. 10F representing calcination at 450° C. for all concentrations tested. Signs of crystalline LLZO (peak at ˜12° 2θ) appear at >5× (or 25% Li excess). Meanwhile crystallization of cubic LLZO at 600° C. is favoured with increasing Li excess (as evidenced by the intensity of the 12° 2θ peak) with best results obtained at 5-7.5% (or 25 to 36% Li excess).

### Example 5: Aging Temperature

A mixed aqueous solution composed of ZrO(NO₃), La(NO₃)₃·6H₂O and Al(NO₃)₃·9H₂O in the stoichiometric ratio of La:Zr:Al=3.0154:2:0.3 was prepared. The pH value was about 0.5. The prepared solution was then dropwise added into diluted LiOH solution. After this neutralization, the final pH value reached 8.5. This suspension was then directly transferred to an 100-mL autoclave with the designated concentration (e.g. total [La]=0.1 M regardless it's in precipitate or supernatant), which was then heated to 150, 200 and 240° C., respectively, for 3 hours including ramping and holding. After aging 3 hours, the wet precipitate was recovered via centrifugation and washed with water and isopropanol thoroughly. The recovered precipitate was then mixed manually with designated quantity of LiOH (excess [Li] for calcination is 1 times higher with respect to [Al] (equivalent to 5% excess Li). The [Al] corresponds to the stoichiometry of Li_{6.1}Al_{0.3}La₃Zr₂O₁₂) (no ball milling). Finally, the ground mixture was separated from the grinding media and drying at 80° C. under vacuum. The completely dry precipitate/LiOH mixture was then calcined at from 400 to 1050° C. for 6 hours to obtain LLZO nanocrystals.

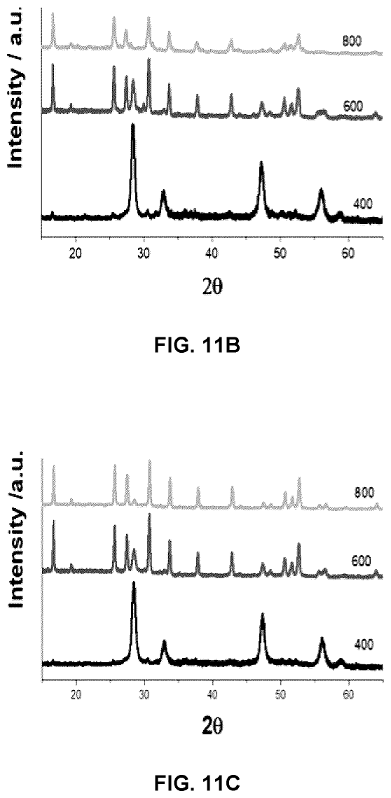

FIGS. 11A-11C show the XRD patterns of LLZO nanocrystals obtained. Cubic LLZO was obtained after calcination at 600° C. and 800° C. independent of the aging temperature of 150, 200 and 240° C. Interestingly the LLZO formed after calcination at 800° C. was a mixture of cubic and tetragonal phases due to insufficient excess Li to compensate evaporation losses. Meanwhile the XRD pattern of the material formed at 400° C. corresponds to the intermediate phase: La₂Zr₂O₇.

### Example 6: Process without Aqueous-Based Aging

A mixed aqueous solution composed of ZrO(NO₃), La(NO₃)₃·6H₂O and Al(NO₃)₃·9H₂O in the stoichiometric ratio of La:Zr:Al=3.0154:2:0.3 was prepared. The pH value was about 0.5. The prepared solution was then dropwise added into diluted LiOH solution. After this neutralization, the final pH value reached 8.5. The wet precipitate was recovered via centrifugation and washed with water and isopropanol thoroughly. The recovered precipitate was then mixed with designated quantity of LiOH by ball milling with 1 mm ZrO₂ balls at 650 rpm for 12 cycles of 5 min grinding/5 min resting. Excess [Li] for calcination was 5 times higher with respect to [Al] or 25% excess. The [Al] corresponds to the stoichiometry of Li_{6.1}Al_{0.3}La₃Zr₂O₁₂). Finally, the ground mixture was separated from the grinding media and dried at 80° C. under vacuum. The completely dried precipitate/LiOH mixture was then calcined at the temperature range from 450 to 800° C. for 6 hours to obtain LLZO nanocrystals.

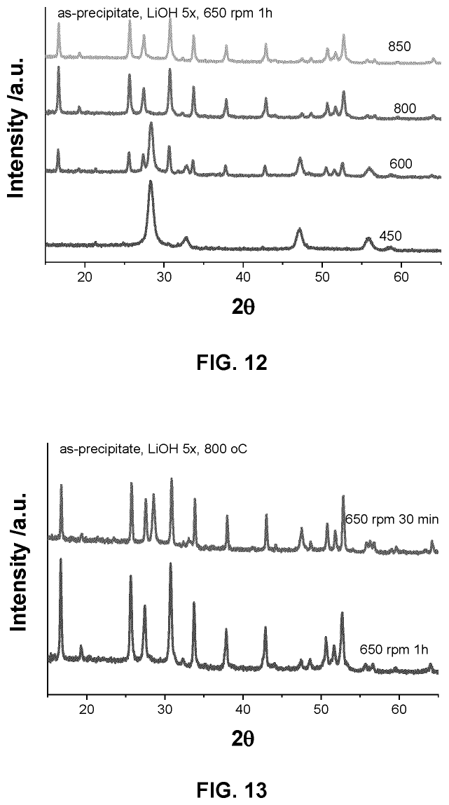

FIG. 12 shows XRD pattern of LLZO nanocrystals prepared from the aging-free recipe. Partially crystalline cubic LLZO was obtained after calcination at 600° C. High purity of cubic LLZO crystals were obtained at 800 and 850° C.

A mixed aqueous solution composed of ZrO(NO₃), La(NO₃)₃·6H₂O and Al(NO₃)₃·9H₂O in the stoichiometric ratio of La:Zr:Al=3.0154:2:0.3 was prepared. The pH value was about 0.5. The prepared solution was then dropwise added into diluted LiOH solution. After this neutralization, the final pH value reached 8.5. The recovered precipitate was then mixed with designated quantity of LiOH by ball milling with 1 mm ZrO₂ balls at 650 rpm for 10 cycles of 3 min grinding/7 min resting. Excess [Li] for calcination was 5 times higher with respect to [Al] or 25% excess. The [Al] corresponds to the stoichiometry of Li_{6.1}Al_{0.3}La₃Zr₂O₁₂). Half of the ground precipitate/LiOH mixture was collected and the other half was ground again for another 10 cycles (i.e., in the end, 20*3 mins). Finally, the two ground samples were separated from the grinding media and dried at 80° C. under vacuum. The completely dry precipitate/LiOH samples were then calcined at 800° C. for 6 hours to obtain LLZO nanocrystals.

FIG. 13 shows the XRD patterns of LLZO nanocrystals prepared from non-aged precipitates. Prolonged ball milling of precipitate/LiOH mixture prior to calcination results in higher cubic LLZO formation efficiency.

### Example 7: ZrCl₄ as a Zr Precursor

Two mixed aqueous solutions composed of ZrCl₄, La(NO₃)₃·6H₂O and Al(NO₃)₃·9H₂O in the stoichiometric ratio of La:Zr:Al=3.0154:2:0.1 were prepared. The pH value was about 0.5. The prepared solutions were then dropwise added into diluted LiOH solution. After this neutralization, the final pH value reached 8.5. One suspension was then directly transferred to an 100-mL autoclave with the designated concentration (e.g. total [La]=0.1 M regardless if it's in precipitate or supernatant), which was then heated to 200° C. for 3 hours including ramping and holding. The precipitate from the other prepared suspension was recovered by centrifugation and thoroughly washed with deionized water (with the purpose of removing/reducing the chloride anions entrained in the solids), then re-dispersed in LiOH solution with pH 8.5. After aging at 200° C. for 3 hours, the wet precipitates from both tests were recovered via centrifugation and washed with water and isopropanol thoroughly. The recovered aged precipitates were then mixed with designated quantity of LiOH (stoichiometric amount only, no excess Li) manually (no ball milling). Finally, the ground mixtures were separated from the grinding media and dried at 80° C. under vacuum. The completely dry precipitate/LiOH mixtures were then calcinated at 600 and 800° C. for 6 hours to obtain LLZO nanocrystals.

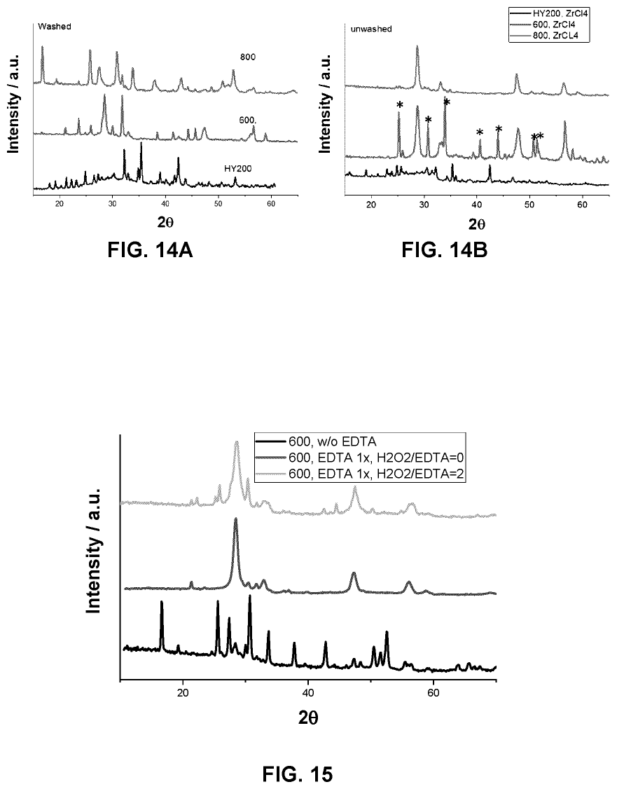

FIG. 14A (washed) and FIG. 14B (unwashed) show the XRD patterns of LLZO nanocrystals prepared where ZrCl₄ was used as the Zr-source. Cubic LLZO was obtained only at 800° C. and only after washing of the precipitate and re-dispersed in LiOH-containing de-ionized water prior to aging. Otherwise LiOCl (marked as * on FIG. 14B) formed instead in the case the original suspension was transferred as is to the autoclave without washing. No LLZO formed at 600° C. calcination.

### Example 8: Effect of Organic Additives

A mixed aqueous solution composed of ZrO(NO₃), La(NO₃)₃·6H₂O and Al(NO₃)₃ 9H₂O in the stoichiometric ratio of La:Zr:Al=3.0154:2:0.1 was prepared. Organic additive (Ethylenediaminetetraacetic acid, EDTA) was added in the molar ratio of EDTA/[La+Zr+Al]=1. The pH of EDTA containing mixing solution was about 10.5 after adjusting with diluted LiOH. In one case H₂O₂ was added together with EDTA in the molar ratio of H₂O₂/EDTA=2. The two suspensions were then directly transferred to a 100-mL autoclave with the designated concentration (e.g. total [La]=0.1 M regardless it's in precipitate or supernatant), which were then heated to 220° C. for 3 hours including ramping and holding. After aging at 220° C. for 3 hours, the wet precipitates were recovered via centrifugation and washed with water and isopropanol thoroughly. The recovered aged precipitates were then mixed with designated quantity of LiOH (stoichiometric amount only, no excess Li) manually (no ball milling). Finally, the ground precipitate/LiOH mixtures were separated from the grinding media and dried at 80° C. under vacuum. The completely dry precipitate/LiOH mixtures were then calcinated at 600° C. for 6 hours to obtain LLZO nanocrystals.

FIG. 15 shows the XRD patterns of calcined products prepared in the presence of EDTA (with and w/o co-addition of H₂O₂) along the XRD pattern obtained in the absence of EDTA. No LLZO was produced in the presence of EDTA. The carbon in EDTA is demonstrated to impede the formation of LLZO.

The scope is indicated by the appended claims.

1. A method of producing LLZO having a cubic crystal phase comprising:
providing an aqueous phase comprising zirconium (Zr) and lanthanum (La), the aqueous phase having a pH between 7 and 14;
forming an intermediate comprising crystalline La(OH)₃ and amorphous Zr hydroxide from the Zr and the La in the aqueous phase;
recovering and washing the intermediate to obtain a washed intermediate; and
heat treating the washed intermediate with a Li precursor at a temperature of from 400 to 850° C. to obtain the LLZO.

2. The method of claim 1, further comprising, before providing the aqueous phase, mixing a Zr precursor in the aqueous phase.

3. The method of claim 2, wherein the Zr precursor is selected from the group consisting of Zr oxide, Zr nitrate, Zr oxy-nitrate, Zr chloride, Zr oxy-chloride, Zr sulfate, Zr oxy-sulfate and Zr acetate.

4. The method of claim 1, further comprising, before providing the aqueous phase, mixing a La precursor in the aqueous phase.

5. The method of claim 4, wherein the La precursor is selected from the group consisting of La oxide, La nitrate, La chloride, La sulfate, and La acetate.

6. The method of claim 1, wherein the Li precursor is selected from LiOH, LiNO₃, LiCl, LiBr, Li₂SO₄, lithium acetate, elementary Li, and Li₂O.

7. The method of claim 1, wherein the LLZO has a formula Li_{7±0.3}La_{3±0.3}Zr_{2±0.3}O_{12±0.3}.

8. The method of claim 7, wherein the LLZO further comprises a dopant.

9. The method of claim 8, wherein the dopant is selected from the group consisting of Ta, Nb, Al, Sn, Ge, Si, Li, Na, and K.

10. The method of claim 8, wherein the LLZO has a formula Li_{(7-x)±0.3}D_{y±0.3}La_{3±0.3}Zr_{2±0.3}O_{12±0.3} wherein D is the dopant and 0≤x≤3, 0≤y≤1.

11. The method of claim 7, wherein the mixing comprises providing the La precursor in an excess amount over a stoichiometric ratio La:Zr=3:2 of up to 10%.

12. The method of claim 7, wherein heat treating step comprises providing the Li precursor in an excess over a stoichiometric ratio Li:La:Zr=7:3:2 of from 0% to 200%.

13. The method of claim 1, further comprising before providing the aqueous phase, mixing the Zr precursor and the La precursor then adjusting the pH of the aqueous phase to be between 7 to 14.

14. The method of claim 1, further comprising before providing the aqueous phase, providing a first aqueous phase comprising the Zr precursor and a second aqueous phase comprising the La precursor, adjusting the pH of the first aqueous phase and/or the second aqueous phase such that aqueous phase obtained from mixing the first aqueous phase and the second aqueous phase has a pH of between 7 to 14.

15. The method of claim 1, wherein the pH is between 8.5 and 10.5.

16. The method of claim 1, further comprising aging the intermediate.

17. The method of claim 16, wherein the aging comprises holding at a temperature of 4° C. to 270° C. for 2 h to 7 days.

18. The method of claim 1, wherein the washing comprises using a solvent selected from the group consisting of water, isopropanol, ethanol, acetone and the mixture thereof.

19. The method of claim 1, wherein the LLZO has a size of between 50 nm to 1 μm.

20. The method of claim 1, wherein the steps of providing, forming, and recovering are performed in a controlled environment substantially free of CO₂.
